(19) United States
(12) Patent Application Publication
(10) Pub. No.: US 2025/0192054 A1
(43) Pub. Date: Jun. 12, 2025

(54) SECOND AIR GAP TYPE FOR SUBTRACTIVE INTERCONNECTS

(71) Applicant: International Business Machines Corporation, Armonk, NY (US)

(72) Inventors: Nicholas Anthony Lanzillo, Wynantskill, NY (US); Ruilong Xie, Niskayuna, NY (US); Koichi Motoyama, Clifton Park, NY (US); James P Mazza, Saratoga Springs, NY (US); Shay Reboh, Guilderland, NY (US); Biswanath Senapati, Mechanicville, NY (US); Utkarsh Bajpai, Delmar, NY (US); Shahrukh Khan, Sandy Hook, CT (US)

(21) Appl. No.: 18/533,683

(22) Filed: Dec. 8, 2023

(51) Int. Cl. H01L 23/532; H01L 21/768; H01L 23/528

(52) U.S. Cl. CPC H01L 23/5329; H01L 21/7682; H01L 23/528

(57) ABSTRACT

A semiconductor device includes metal lines disposed in a layer. The metal lines include a first spacing and a second spacing. The second spacing is larger than a minimum pitch between the metal lines. A gapping structure is disposed within the second spacing. A second air gap is disposed adjacent to the gapping structure within the second spacing.

### BACKGROUND

The present invention generally relates to semiconductor devices and processing methods, and more particularly to metal structures having air gaps formed in relaxed interconnect spaces with non-nested interconnects.

Integrated circuit processing includes front end of the line (FEOL), middle of the line (MOL) and back end of the line (BEOL) processes. Layers of interconnections are formed during the BEOL processing to complete the integrated circuit structure. As integrated circuits continue to reduce in size, implementing effective isolation of components becomes increasingly difficult. Effective isolation of components is needed to reduce parasitic capacitive coupling and possible leaking or shorting among metal structures.

The reduction in size of the various components of transistor devices increases related parasitic characteristics, which can impact operational speed of a transistor, energy consumption of the transistor, and other aspects of performance. In general, capacitance is affected, and determined, by the size of the component as well as characteristics of the dielectric material, represented typically by its dielectric constant.

Therefore, a need exists to form metal structures that are properly isolated from one other to reduce parasitic capacitances, charge leaking and possibility of shorts from surrounding conductive structures in high density devices.

### SUMMARY

In accordance with an embodiment of the present invention, a semiconductor device includes a plurality of metal lines disposed in a layer, the metal lines including a first spacing and a second spacing. The second spacing is larger than a minimum pitch between the metal lines. A gapping structure is disposed within the second spacing. A second air gap is disposed adjacent to the gapping structure within the second spacing.

In accordance with another embodiment, a semiconductor device includes a plurality of metal lines disposed in a layer, the metal lines including a first spacing associated with a minimum pitch and a second spacing being larger than a minimum pitch between the metal lines. A first air gap is disposed within an adhesive liner within the first spacing. A gapping structure is disposed within the second spacing. At least one second air gap is disposed adjacent to the gapping structure within an adhesive liner in the second spacing.

In accordance with another embodiment of the present invention, a semiconductor device includes a plurality of metal lines disposed in a layer, the metal lines having a tapered cross-section wider at a base of the metal line, the metal lines including a first spacing associated with a minimum pitch and a second spacing being larger than a minimum pitch between the metal lines. A first air gap is disposed within an adhesive liner within the first spacing. A gapping structure is disposed within an adhesive liner within the second spacing, where the gapping structure divides the second spacing into a plurality of smaller spacings to permit formation of one or more second air gaps within the adhesive liner in the second spacing.

In some embodiments, the gapping structure includes sidewall spacers and the second air gap is disposed within the sidewall spacers. The gapping structure can include a divider disposed on an adhesive liner in the second spacing and the second air gap is disposed on at least one side of the divider. The divider can be disposed between two second air gaps. The gapping structure can include a dummy metal line and the second air gap is disposed within the dummy metal line. The dummy metal line can include an additional second air gap disposed on at least one side of the dummy metal line. The dummy metal line can be disposed between two second air gaps. The dummy metal line can include silicon nitride. A first air gap can optionally be disposed within the first spacing.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a semiconductor device having a metal layer formed on a dielectric layer over a substrate, in accordance with an embodiment of the present invention;

FIG. 2 shows a cross-sectional view of the semiconductor device with metal lines subtractively etched from the metal layer and having at least two spacings between the metal lines, in accordance with an embodiment of the present invention;

FIG. 3 shows a cross-sectional view of the semiconductor device with the metal lines encapsulated in an adhesion liner which forms a first type of air gap, in accordance with an embodiment of the present invention;

FIG. 4 shows a cross-sectional view of the semiconductor device with a gapping structure formed in the second spacing, which includes sidewall spacers formed on the adhesion liner, in accordance with an embodiment of the present invention;

FIG. 5 shows a cross-sectional view of the semiconductor device with the gapping structure encapsulated in an adhesion liner which forms a second type of air gap, in accordance with an embodiment of the present invention;

FIG. 6 shows a cross-sectional view of the semiconductor device of FIG. 3 having a dielectric fill formed in the second spacing on the adhesion liner, in accordance with an embodiment of the present invention;

FIG. 7 shows a cross-sectional view of the semiconductor device with a gapping structure formed in the second spacing, which includes a divider formed on the adhesion liner, in accordance with an embodiment of the present invention;

FIG. 8 shows a cross-sectional view of the semiconductor device with the gapping structure encapsulated in an adhesion liner which forms second type air gaps, in accordance with an embodiment of the present invention;

FIG. 9 shows a cross-sectional view of a semiconductor device having a metal layer formed thereon, in accordance with an embodiment of the present invention;

FIG. 10 shows a cross-sectional view of the semiconductor device with metal lines subtractively etched from the metal layer and having a single spacing between the metal lines, in accordance with an embodiment of the present invention;

FIG. 11 shows a cross-sectional view of the semiconductor device with the metal lines encapsulated in an organic planarizing layer, in accordance with an embodiment of the present invention;

FIG. 12 shows a cross-sectional view of the semiconductor device with a metal line removed to create a second spacing between metal lines, in accordance with an embodiment of the present invention;

FIG. 13 shows a cross-sectional view of the semiconductor device with a gapping structure formed in the second spacing, which includes a dummy metal line including a second air gap type within a central portion thereof, in accordance with an embodiment of the present invention; and

FIG. 14 shows a cross-sectional view of the semiconductor device with the gapping structure encapsulated in adhesion liner which forms first and second type air gaps, in accordance with an embodiment of the present invention.

### DETAILED DESCRIPTION

In accordance with embodiments of the present invention, devices and methods are described which employ air gap structures for non-nested interconnect lines. In many semiconductor device designs interconnects structures include nested and non-nested interconnects. Interconnects are metal lines that connect various components and can be employed at different levels in back end of the line (BEOL) structures. Nested interconnects include a tight pitch and are usually spaced at or near a critical dimension spacing (e.g., at the limit of lithographic patterning). Non-nested interconnects can include larger spacings and can be referred to as relaxed spacings between metal interconnects. In some semiconductor layouts, non-nested interconnect lines can make up, e.g., 50% or more of a routed design. The reliability of non-nested interconnects therefor contributes greatly to the operation and performance of a semiconductor device. Further, in accordance with embodiments of the present invention, introducing second type air gaps for non-nested metal lines can result in line capacitance reduction of up to 30%. In one example, line capacitances were reduced from over 0.2 fF/micron to less than 0.15 fF/micron.

In accordance with embodiments of the present invention, air gap structures are formed within non-nested spacings to reduce parasitic capacitances and provide dielectric isolation benefits to non-nested as well as nested interconnects. In one embodiment, the air gap structures are formed in a non-nested spacing where the interconnects are formed by subtractive etching. Subtractive etching is performed on a metal sheet and forms tapered metal lines having a narrower top portion than a bottom portion. The subtractive etching within a level of interconnect wiring can provide at least two different spacings between interconnect lines, e.g., a first spacing can include a nested spacing and a second spacing can include a non-nested or relaxed spacing. Other types of spacing can also be employed.

The first spacing may or may not include a first air gap type embedded in a first dielectric material. The second spacing includes one or more of a second air gap type embedded in a second dielectric material. The second air gap type can have different heights and widths than the first air gap type. In useful embodiments, the second spacing can include one, two or three air gaps. The first and second dielectric materials can be the same or different materials. In other embodiments, the metal interconnects can be formed by deposition rather than subtractive etching.

The interconnects with air gaps in accordance with embodiments of the present invention can be part of any metal layer (M1, M2, M3, etc.) or can be employed with other structures, e.g., backside power rails (BSPRs). For example, the interconnects can include, e.g., supply voltage (Vdd) and ground (Vss) backside power rails and have first and second air gap types employed within the spacings of the BSPR layer.

In accordance with an embodiment of the present invention, a semiconductor device includes a plurality of metal lines disposed in a layer, the metal lines including a first spacing and a second spacing. The second spacing is larger than a minimum pitch between the metal lines. A gapping structure is disposed within the second spacing. A second air gap is disposed adjacent to the gapping structure within the second spacing. The second air gaps are formed in relaxed spacings, which tend to be too large to form air gaps. By incorporating gapping structures, second air gaps or second type air gaps can be formed in relaxed spacing areas, which make up a large portion of a chip. These second air gaps improve performance by increasing dielectric isolation and reducing crosstalk between metal lines.

In accordance with another embodiment, a semiconductor device includes a plurality of metal lines disposed in a layer, the metal lines including a first spacing associated with a minimum pitch and a second spacing being larger than a minimum pitch between the metal lines. A first air gap is disposed within an adhesive liner within the first spacing. A gapping structure is disposed within the second spacing. At least one second air gap is disposed adjacent to the gapping structure within an adhesive liner in the second spacing.

In accordance with another embodiment of the present invention, a semiconductor device includes a plurality of metal lines disposed in a layer, the metal lines having a tapered cross-section wider at a base of the metal line, the metal lines including a first spacing associated with a minimum pitch and a second spacing being larger than a minimum pitch between the metal lines. A first air gap is disposed within an adhesive liner within the first spacing. A gapping structure is disposed within an adhesive liner within the second spacing, where the gapping structure divides the second spacing into a plurality of smaller spacings to permit formation of one or more second air gaps within the adhesive liner in the second spacing.

In some embodiments, the gapping structure includes sidewall spacers and the second air gap is disposed within the sidewall spacers. The gapping structure can include a divider disposed on an adhesive liner in the second spacing and the second air gap is disposed on at least one side of the divider. The divider can be disposed between two second air gaps. The gapping structure can include a dummy metal line and the second air gap is disposed within the dummy metal line. The dummy metal line can include an additional second air gap disposed on at least one side of the dummy metal line. The dummy metal line can be disposed between two second air gaps. The dummy metal line can include silicon nitride. A first air gap can optionally be disposed within the first spacing.

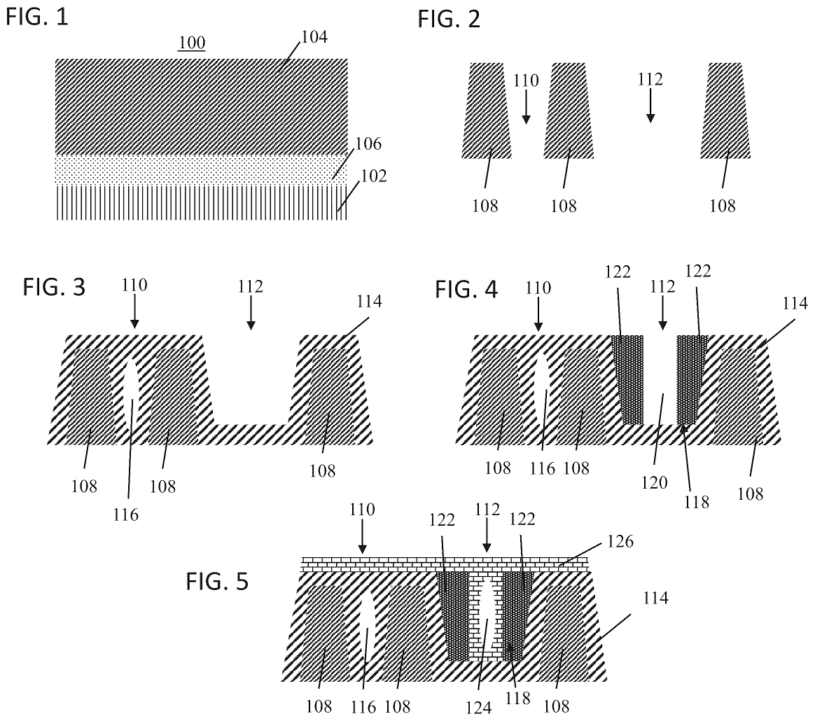

Referring now to the drawings in which like numerals represent the same or similar elements and initially to FIG. 1, devices and methods for manufacturing a semiconductor device 100 are shown in accordance with embodiments of the present invention. Semiconductor device 100 includes a substrate 102 having multiple layers on which metal interconnects will be fabricated. FIG. 1 depicts a cross-sectional view of a metal layer 104 deposited on the substrate 102.

The substrate 102 can include any suitable substrate structure and will depend on the point of fabrication where the metal interconnects for the device are to be fabricated. In one example, the substrate 102 includes, e.g., a bulk semiconductor, a semiconductor-on-insulator (SOI) substrate, etc., and preferably includes a monocrystalline semiconductor with front end of the line (FEOL) and middle end of the line (MOL) structures formed thereon.

In one example, the substrate 102 can include a silicon-containing material. Illustrative examples of Si-containing materials suitable for the substrate 102 can include, but are not limited to, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc. The substrate 102 can include interlevel dielectric layers and metal structures from previous processing.

The substrate 102 can include a dielectric layer 106, such as, e.g., an interlevel dielectric layer (ILD). The dielectric layer 106 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SILK™, other carbon containing materials, organo-inorganic materials such as spin-on glasses and silsesquioxane-based materials, and diamond-like carbon (DLC), also known as amorphous hydrogenated carbon, α-C: H). The dielectric layer 106 can be deposited using chemical vapor deposition (CVD), although other deposition methods can be employed.

A conductive deposition is performed on top of the dielectric layer 106. The conductive deposition can include materials, such as, e.g., Cu, Ru, Mo, Rh, W, Ir, and alloys or combinations of these and other conductive materials. In a particularly useful embodiment, the conductive deposition includes Ru. The conductive deposition can be performed using a deposition method, such as, e.g., CVD, plasma enhanced CVD (PECVD), atomic layer deposition (ALD) or any other suitable deposition method. The conductive deposition can be planarized, e.g., by chemical mechanical polishing (CMP).

Referring to FIG. 2, a subtractive metal etch process is employed to pattern the metal layer 104. In one embodiment, a hard mask (not shown) may be formed by blanket depositing a layer of hard mask material, providing a patterned photoresist on top of the layer of hard mask material, and then etching the layer of hard mask material to provide the hard mask pattern for etching metal layer 104. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

The hard mask can be employed to subtractively etch first spacings 110 and second spacings 112 to from metal lines 108. The metal etch process can include an anisotropic etch. e.g., a reactive ion etch (RIE) etch or ion beam etch (IBE etch). The anisotropic etch, such as a plasma dry etch, is accurately controlled since a lithographic process is employed.

It should be understood that more than two different spacings can be formed by the subtractive metal etch process. FIG. 2 shows the first spacing 110 including a critical dimension that yields a smallest permitted width enabled by lithographical processing. The first spacing 110 can therefore be a minimum pitch for metal lines 108. The second spacing 112 provides a greater width for a relaxed spacing for non-nested metal lines.

The subtractive metal etch forms metal lines 108 having a narrower top portion and a wider base. While the subtractive metal etch can be employed to pattern a deposited metal, other metal line formation processes can also be employed and benefit in accordance with embodiments of the present invention.

Referring to FIG. 3, an adhesion liner 114 is deposited over metal lines 108 and lines the spacings 110 and 112. The adhesion liner 114 can be deposited conformally by physical vapor deposition (PVD), CVD, ALD, or the like, to line the surfaces of metal lines 108 and spacings 110 and 112. The adhesion liner 114 can include SiO₂, SiN, SiOC, SiOCN, SiBCN, or the like. In useful embodiments, ultra-low dielectric constant (K) materials (ULK) can be employed (e.g., K less than about 2.7) for adhesion liner 114, and, in particular, porous forms of this material can be employed to assist in reducing crosstalk between metal lines or other conductive structures.

The adhesion liner 114 is formed to a thickness sufficient to pinch off or otherwise fill the volume at a top portion of the metal lines 108 with spacing 110 while forming an air gap 116 substantially vertically along mid to lower portions of the metal lines having spacing 110. The air gap 116 is formed as a void within adhesion liner 114. The air gap 116 can be considered a first type of air gap formed between metal lines 108 having the first spacing 110.

Referring to FIG. 4, a dielectric layer 118 is formed over the adhesion liner 114 and fills the spacing 112. The dielectric layer 118 includes a material that is selectively removeable relative to the adhesion liner 114. For example, if the adhesion liner 114 includes a silicon nitride, dielectric layer 118 can include a silicon oxide or silicon oxynitride to be selectively etchable with respect to the adhesion liner 114. A CMP process can be employed to planarize the free surface of the dielectric layer 118.

An etch is performed to remove a center portion of the dielectric layer 118 formed in spacing 112. The dielectric layer 118 forms an opening 120 down to the adhesion liner 114 to create sidewall spacers 122 within the spacing 112. The sidewall spacers 122 are disposed on the adhesion liner 114 and together form a gapping structure, which will be employed in generating air gaps.

In one embodiment, an isotropic etch is performed to create the opening 120. In this way, no mask is needed to pattern the sidewall spacers 122. The isotropic etch process can be timed to ensure that a proper dimension of the opening 120 is achieved. The opening 120 permits the formation of a second type of air gap as will be described.

Referring to FIG. 5, a second adhesion liner 126 is deposited. The second adhesion liner 126 fills opening 120 and forms an air gap 124. The air gap 124 is a second type of air gap that is formed within the spacing 112. This second air gap type for air gap 124 is formed using the sidewall spacers 122 to pinch off the adhesion liner material during deposition. The second adhesion liner 126 can be deposited by PVD, CVD, ALD, or the like, to line the surfaces of sidewall spacers 122 within spacing 112. The second adhesion liner 126 can include a same material as the adhesion liner 114, although a different material can also be selected.

Processing can continue with the formation of additional metal structures and the completion of the device 100. The additional metal structures can include first type air gaps 116 and second type air gaps 124. In some embodiments, first type air gaps 116 can be omitted.

In accordance with embodiments of the present invention, air gaps work in conjunction with dielectric material, e.g., to electrically isolate metal lines from one another, reduce crosstalk and reduce the possibility of shorts.

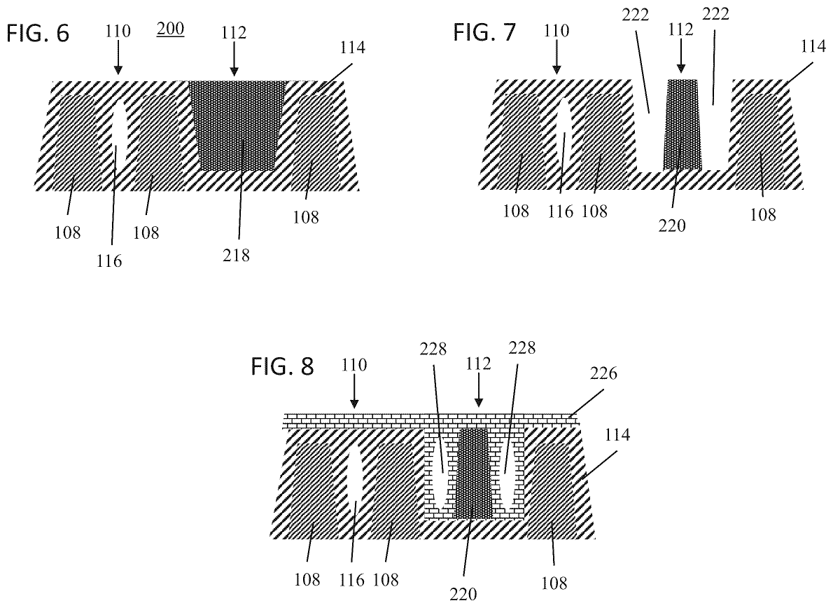

Referring to FIG. 6, devices and methods for manufacturing a semiconductor device 200 are shown in accordance with another embodiment of the present invention. Beginning with the structure shown in FIG. 3, a dielectric layer 218 is formed over the adhesion liner 114 and fills the spacing 112. The dielectric layer 218 includes a material that is selectively removeable relative to the adhesion liner 114. For example, if the adhesion liner 114 includes a silicon nitride, dielectric layer 218 can include a silicon oxide or silicon oxynitride to be selectively etchable with respect to the adhesion liner 114. A CMP process can be employed to planarize the free surface of the dielectric layer 218.

Referring to FIG. 7, an etch is performed to form a divider 220 by removing the dielectric layer 218 from openings 222. The divider 220 is disposed on the adhesion liner 114 and forms a gapping structure, which will be employed in generating air gaps. The dielectric layer 218 is patterned using a hard mask (not shown).

In one embodiment, the hard mask may be formed by blanket depositing a layer of hard mask material, providing a patterned photoresist on top of the layer of hard mask material, and then etching the layer of hard mask material to provide the hard mask pattern to etch the divider 220. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process. The hard mask is then employed to remove material to form openings 222 by an etch process, e.g., RIE or IBE. The openings 222 are sized to permit the formation of a second type of air gap as will be described.

Referring to FIG. 8, a second adhesion liner 226 is deposited. The second adhesion liner 126 fills opening 120 and forms air gaps 228. The air gaps 228 are a second type of air gap that is formed within the spacing 112. This second air gap type for air gaps 228 are formed using the divider 220 to form two gap spaces such that during deposition of the second adhesion liner 226 pinch off the adhesion liner material occurs on sides of the divider 220. This results in two air gaps 228 being formed in spacing 112. The second adhesion liner 226 can be deposited by PVD, CVD, ALD, or the like, to line the surfaces of adhesion liner 114 and divider 220 within spacing 112. The second adhesion liner 226 can include a same material as the adhesion liner 114, although a different material can also be selected.

Processing can continue with the formation of additional metal structures and the completion of the device 200. The additional metal structures can include first type air gaps 116 and second type air gaps 228. In some embodiments, first type air gaps 116 can be omitted.

In accordance with embodiments of the present invention, air gaps work in conjunction with dielectric material, e.g., to electrically isolate metal lines from one another, reduce crosstalk and reduce the possibility of shorts.

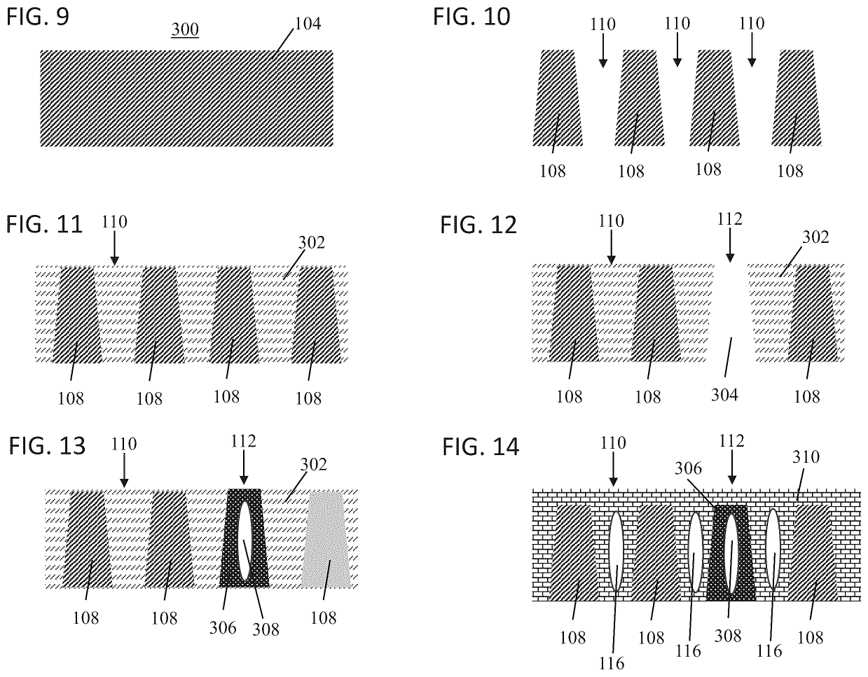

Referring to FIG. 9, devices and methods for manufacturing a semiconductor device 300 are shown in accordance with another embodiment of the present invention. A conductive deposition is performed on top of a dielectric layer (106, FIG. 1). The conductive deposition can include materials, such as, e.g., Cu, Ru, Mo, Rh, W, Ir, and alloys or combinations of these and other conductive materials. In a particularly useful embodiment, the conductive deposition includes Ru. The conductive deposition can be performed using a deposition method, such as, e.g., CVD, PECVD, ALD or any other suitable deposition method. The conductive deposition can be planarized, e.g., by CMP.

Referring to FIG. 10, a subtractive metal etch process is employed to pattern the metal layer 104. In one embodiment, a hard mask (not shown) may be formed by blanket depositing a layer of hard mask material, providing a patterned photoresist on top of the layer of hard mask material, and then etching the layer of hard mask material to provide the hard mask pattern for etching metal layer 104. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

The hard mask can be employed to subtractively etch first spacings 110 to form metal lines 108. The metal etch process can include an anisotropic etch, e.g., RIE or IBE. The anisotropic etch, such as a plasma dry etch, is accurately controlled since a lithographic process is employed.

It should be understood that a single spacing is formed by the subtractive metal etch process. The first spacing 110 can include a minimum pitch for metal lines 108. The subtractive metal etch forms metal lines 108 having a narrower top portion and a wider base. While the subtractive metal etch can be employed to pattern a deposited metal, other metal line formation processes can also be employed and benefit in accordance with embodiments of the present invention.

Referring to FIG. 11, in one embodiment, an organic planarization layer (OPL) 302 is formed over the device 300. The OPL 302 fills in the spacings 110 and is self-leveling.

Referring to FIG. 12, an anti-reflective coating (ARC) layer (not shown) may be formed on the OPL 302 followed by a layer of photoresist (not shown) formed on the ARC layer. The layer of photoresist can be imaged with an image pattern and developed to form an etch mask. One metal line 108 can be selectively etched in accordance with the etch mask to remove metal lines to form opening 304. With the removal of one or more metal lines, the second spacings 112 are achieved.

Referring to FIG. 13, a deposition process can be performed to fill the opening 304. In one embodiment, a plasma-assisted deposition can be performed, preferably at a low temperature to remain consistent with the OPL 302. In one embodiment, the plasma-assisted deposition can deposit a dielectric material in a shape of a dummy metal line 306. e.g., silicon nitride, in the opening 304 to form air gap 308 inside the dummy metal line 306. The dummy metal line 306 is disposed within the adhesion liner 310 and forms a gapping structure, which will be employed in generating air gaps.

In one embodiment, the OPL 302 can be replaced by a dielectric material and the structure depicted in FIG. 13 can be employed with a single air gap 308 formed in the dielectric material. However, the OPL 302 can be replaced using an adhesion liner and additional air gaps can be formed.

Referring to FIG. 14, the OPL 302 is stripped or removed. The OPL 302 can be removed by employing an ashing process. An adhesion liner 310 is deposited over metal lines 108 and dummy metal line 306. The adhesion liner 310 can be deposited conformally by PVD, CVD, ALD, or the like, to line the surfaces of metal lines 108 and dummy metal line 306 in spacings 110. The adhesion liner 310 can include SiO₂, SiN, SiOC, SiOCN, SiBCN, or the like. In useful embodiments, ultra-low dielectric constant (K) materials (ULK) can be employed (e.g., K less than about 2.7) for adhesion liner 310, and, in particular, porous forms of this material can be employed to assist in reducing crosstalk between metal lines or other conductive structures.

The adhesion liner 310 is formed to a thickness sufficient to pinch off or otherwise fill the volume at a top portion of the metal lines 108 while forming an air gap 116 substantially vertically along mid to lower portions of the metal lines having spacing 110 therebetween. The air gap 116 is formed as a void within adhesion liner 310. The air gap 116 can be considered a second type of air gap formed between metal lines 108 having within a second spacing 112.

Processing can continue with the formation of additional metal structures and the completion of the device 300. The additional metal structures can include air gaps 116 and second type air gaps 308. In some embodiments, first type air gaps 116 can be omitted.

In accordance with embodiments of the present invention, air gaps work in conjunction with dielectric material, e.g., to electrically isolate metal lines from one another, reduce crosstalk and reduce the possibility of shorts.

It should be understood that illustrative examples of gapping structures (e.g., sidewall spacers 122, divider 220, dummy metal line 306, etc.) are described; however these gapping structures and others can be combined or substituted as needed. For example, multiple dividers 220 can be employed in a single second spacing, or dummy metal lines and one or more sidewall spacers can be combined in a single second spacing, etc.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below.” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a plurality of metal lines disposed in a layer, the plurality of metal lines including a first spacing and a second spacing, the second spacing being larger than a minimum pitch between the metal lines;
a gapping structure disposed within the second spacing; and
a second air gap disposed adjacent to the gapping structure within the second spacing.

2. The semiconductor device as recited in claim 1, wherein the gapping structure includes sidewall spacers and the second air gap is disposed within the sidewall spacers.

3. The semiconductor device as recited in claim 1, wherein the gapping structure includes a divider disposed on an adhesive liner in the second spacing and the second air gap is disposed on at least one side of the divider.

4. The semiconductor device as recited in claim 3, wherein the divider is disposed between two second air gaps.

5. The semiconductor device as recited in claim 1, wherein the gapping structure includes a dummy metal line and the second air gap is disposed within the dummy metal line.

6. The semiconductor device as recited in claim 5, wherein the dummy metal line includes an additional second air gap disposed on at least one side of the dummy metal line.

7. The semiconductor device as recited in claim 6, wherein the dummy metal line is disposed between two second air gaps.

8. The semiconductor device as recited in claim 5, wherein the dummy metal line includes silicon nitride.

9. The semiconductor device as recited in claim 1, wherein a first air gap is disposed within the first spacing.

10. A semiconductor device, comprising:
a plurality of metal lines disposed in a layer, the plurality of metal lines including a first spacing associated with a minimum pitch and a second spacing being larger than a minimum pitch between the metal lines;
a first air gap is disposed within an adhesive liner within the first spacing;
a gapping structure is disposed within the second spacing; and
at least one second air gap is disposed adjacent to the gapping structure within an adhesive liner in the second spacing.

11. The semiconductor device as recited in claim 10, wherein the gapping structure includes sidewall spacers and the at least one second air gap is disposed within the sidewall spacers.

12. The semiconductor device as recited in claim 10, wherein the gapping structure includes a divider disposed on the adhesive liner in the second spacing and the at least one second air gap is disposed on at least one side of the divider.

13. The semiconductor device as recited in claim 12, wherein the divider is disposed between two second air gaps.

14. The semiconductor device as recited in claim 10, wherein the gapping structure includes a dummy metal line and an air gap is disposed inside the dummy metal line.

15. The semiconductor device as recited in claim 14, wherein an additional second air gap is disposed on at least one side of the dummy metal line.

16. The semiconductor device as recited in claim 15, wherein the dummy metal line is disposed between two second air gaps.

17. The semiconductor device as recited in claim 14, wherein the dummy metal line includes silicon nitride.

18. A semiconductor device, comprising:
a plurality of metal lines disposed in a layer, the plurality of metal lines having a tapered cross-section wider at a base of the metal lines, the plurality of metal lines including a first spacing associated with a minimum pitch and a second spacing being larger than a minimum pitch between the metal lines;
a first air gap is disposed within an adhesive liner within the first spacing; and
a gapping structure is disposed within an adhesive liner within the second spacing, wherein the gapping structure divides the second spacing into a plurality of smaller spacings to permit formation of one or more second air gaps within the adhesive liner in the second spacing.

19. The semiconductor device as recited in claim 18, wherein the gapping structure includes a dummy metal line.

20. The semiconductor device as recited in claim 19, wherein the dummy metal line includes an air gap within a center portion thereof.
